(19) United States
(12) Patent Application Publication
(10) Pub. No.: US 2014/0124888 A1
(43) Pub. Date: May 8, 2014

(54) Image Sensor and Method for Manufacturing the Same

(71) Applicant: Sun CHOI, Icheon-si (KR)

(72) Inventor: Sun CHOI, Icheon-si (KR)

(21) Appl. No.: 13/763,389

(22) Filed: Feb. 8, 2013

(30) Foreign Application Priority Data
Nov. 5, 2012 (KR) 10-2012-0124222

(51) Int. Cl. H01L 31/0232

(52) U.S. Cl. CPC H01L 31/02325
USPC 257/432; 438/70

(57) ABSTRACT

An image sensor having a pixel region, a logic region, and an analog region, that includes a photodiode region in a substrate in the pixel region, an insulating layer on the substrate containing a zero wiring layer in the pixel region, a first wiring layer in the pixel region, the logic region, and the analog region, and a second wiring layer in the logic region and the analog region, a first trench in a portion of the insulating layer in the pixel region, second trenches in a bottom of the first trench to match to the photodiode region, color filter layers in respective second trenches, and microlenses on respective color filter layers.

### CROSS REFERENCE TO RELATED APPLICATION

This application claims the benefit of the Patent Korean Application No. 10-2012-0124222, filed on Nov. 5, 2012, which is hereby incorporated by reference as if fully set forth herein.

### BACKGROUND OF THE DISCLOSURE

1. Field of the Disclosure

Embodiments of the invention relate to an image sensor and a method for manufacturing the same.

2. Discussion of the Related Art

The image sensor is a semiconductor device for converting an optical image to an electric signal. Typical image sensors include a CCD (Charge Coupled Device) image sensor and a CMOS (Complementary Metal Oxide Semiconductor) image sensor.

In comparison to the CCD image sensor, the CMOS image sensor has advantages in that a driving system is simple, a variety of scanning systems can be embodied, a signal processing circuit can be integrated with the unit pixels onto a single chip enabling a smaller product, and power consumption is low. Owing to such advantages, the CMOS image sensor has many applications, such as DSC (Digital Still Camera), PC Camera, Mobile Camera, and so on.

In the CMOS image sensor, there may be 3T type, 4T type, or 5T type CMOS image sensors according to the number of transistors in the unit pixel. The unit pixel may include one photodiode and, depending on the type, at least one transistor (for example, a transfer transistor, a reset transistor, a select transistor, and a drive transistor).

In general, the image sensor may include a microlens for collecting light, a color filter for filtering the collected light, a photodiode for sensing the light passing through the color filter, and at least one transistor electrically connected to the photodiode.

### SUMMARY OF THE DISCLOSURE

Accordingly, the present invention is directed to an image sensor and a method for manufacturing the same.

Objects of the present invention include providing an image sensor which can prevent loss of light and improve sensitivity, and a method for manufacturing the same.

Additional advantages, objects, and features of the disclosure will be set forth in part in the description which follows and in part will become apparent to those having skill in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose(s) of the invention, as embodied and broadly described herein, an image sensor having a pixel region, a logic region, and an analog region, includes a photodiode region in the pixel region of a substrate, an insulating layer on the substrate containing a zero wiring layer in the pixel region, a first wiring layer in the pixel region, the logic region, and the analog region, a second wiring layer in the logic region and the analog region, a first trench in a portion of the insulating layer in the pixel region to match to the pixel region, second trenches in a bottom of the first trench to match to the photodiode region, color filter layers in the respective second trenches, and microlenses on the respective color filter layers.

The color filter layer may have an upper side between the first wiring layer and the second wiring layer.

The color filter layer may be between adjacent zero wiring layers and adjacent first wiring layers.

The color filter layer may have an upper side on the same plane as the bottom of the first trench.

The color filter layer may have an upper side higher than the bottom of the first trench.

The color filter layer may include a plurality of color filters in the second trenches, wherein the bottom of the first trench may be between the color filters.

The microlens(es) may be on the color filters and a lowermost surface of the first trench.

In another aspect of the present invention, a method for manufacturing an image sensor having a pixel region, a logic region, and an analog region, includes the steps of forming a photodiode region in a substrate in the pixel region, forming an insulating layer on the substrate containing a zero wiring layer in the pixel region, a first wiring layer in the pixel region, the logic region, and the analog region, and a second wiring layer in the logic region and the analog region, forming a first trench by etching a portion of the insulating layer in the pixel region matched to the pixel region, forming second trenches by etching a portion of the insulating layer under the first trench, matched to the photodiode region, forming color filter layers in the respective second trenches, and forming microlenses on the respective color filter layers.

The first trench may have a bottom or lowermost surface between the first wiring layer and the second wiring layer. Each of the second trenches may extend from a space between adjacent zero wiring layers to a space between adjacent first wiring layers.

The method may further include the step of forming an etch stop film between the zero wiring layer and the substrate, and each of the second trenches may expose the etch stop film.

The color filter layer may have an uppermost surface on the same plane with, or higher than, the bottom of the first trench.

### Advantageous Effects

The image sensor of the present invention can reduce a length of a light path between the photodiode and the microlens, thereby preventing loss of light, and improve sensitivity.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle(s) of the disclosure. In the drawings:

FIG. 1 illustrates a section of an image sensor in accordance with an embodiment of the invention.

FIGS. 2A to 2E illustrate sections showing the steps of an exemplary method for manufacturing an image sensor in accordance with an embodiment of the invention.

FIG. 3 illustrates a section of an image sensor in accordance with another embodiment of the invention.

### DESCRIPTION OF SPECIFIC EMBODIMENTS

Reference will now be made in detail to the specific embodiments of the present invention, examples of which are illustrated in the accompanying drawings. In the description of the various embodiments, if a layer, a film, a region, a pattern, or a structure is “on” or “under” a substrate, a layer, a film, a region, a pad, or a pattern, “on” or “under” implies that the layer, the film, the region, the pattern, or the structure is “on” or “under” the substrate, the layer, the film, the region, the pad, or the pattern directly or indirectly, and may include one or more other substrates, layers, films, regions, pads, or patterns therebetween. In addition, a reference to the structure “on” or “under” another structure may be in the drawings.

Sizes in the drawings can be exaggerated, omitted or shown schematically for convenience and clarity of description. In addition, a size of an element may not be shown to scale, perfectly. Moreover, the same reference number refers to the same elements throughout description of the drawings. The present image sensor will be described with reference to the attached drawings.

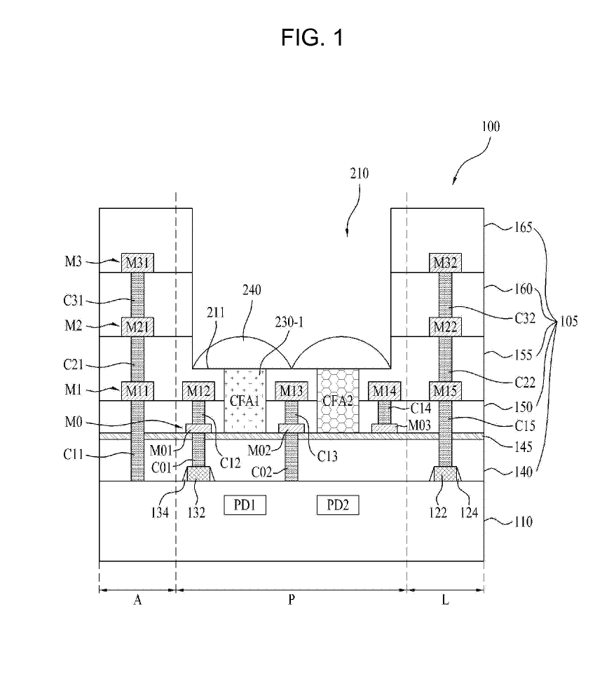

FIG. 1 illustrates a cross-section of an image sensor 100 in accordance with an embodiment of the invention. Referring to FIG. 1, the image sensor 100 may comprise a pixel region P, a logic region L, and an analog region A.

The pixel region P may be a region having a pixel therein configured to sense light, and the logic region L may comprise a region having a logic device or circuit therein for processing the light sensed at the pixel region P into an electric signal thereby converting the light into a data signal. The analog region may comprise a region containing an analog device.

The image sensor 100 includes a substrate 110, photodiode regions PD1 and PD2, a pixel gate 132, a logic gate 122, a first insulating layer 140, an etch stop film 145, a second insulating layer 150, a zero wiring layer M0, first to third wiring layers M1, M2, and M3, third to fifth insulating layers 155, 160 and 165, a plurality of contacts C01˜C02, C11˜C15, C21˜C22 and C31˜C32, a color filter layer 230-1, and microlenses 240.

The pixel region P of the image sensor 100 includes a plurality of unit pixels, and FIG. 1 illustrates only one of the unit pixels. The unit pixel may refer to a region having a pixel which is a smallest unit for sensing light and processing the electrical signal therefrom.

The substrate 110 may be a semiconductor substrate (for example, a silicon substrate), and may include an epitaxial layer formed by an epitaxial process. The substrate 110 may further include an isolation layer (not shown) for isolating an active region of the substrate from an isolation region.

The photodiode regions PD1 and PD2 may be provided in the substrate 110 in the pixel region P. For example, the photodiode regions PD1 and PD2 may be in an active region of the substrate 110, which comprises an n type impurity region having n type impurity injected into a p type semiconductor substrate 110. In this case, a PN junction may be formed between the p type semiconductor substrate 110 and the n type impurity region. Also, there may be another p type impurity region formed in the surface of the substrate 110 on the n type impurity region for preventing a dark current.

The pixel gate 132 may be on the substrate 110 in the pixel region P, and the logic gate 122 may be on the substrate 110 in the logic region L. The pixel gate 132 may have a structure comprising a stack including a pixel gate insulating film (not shown) and a pixel gate electrode (not shown), and may have a spacer formed at a sidewall thereof. And, the logic gate 122 may have a structure comprising a stack including a logic gate insulating film (not shown), and a logic gate electrode (not shown), and may have a logic spacer 124 formed at a sidewall thereof.

The pixel gate 132 may be a gate of a transistor (for example, Tx, Rx, Dx, or Sx) of the unit pixel of the image sensor 100. For example, the pixel gate 132 shown in FIG. 1 may be a gate of the transfer transistor Tx. There may be a source region and a drain region (not shown) in the substrate 110 in the pixel region P on opposed sides or on one side of at least one of the pixel gates of the transistors Tx, Rx, Dx, and Sx. In addition, a source region and a drain region (not shown) may be provided in the substrate 110 in the logic region L on opposed sides or one side of the logic gate 122.

The insulating layer 105 may be formed on the substrate. The insulating layer 105 may include the zero wiring layer M0 in the pixel region P, the first wiring layer M1 in the pixel region P, the logic region L, and the analog region A, the second and third wiring layers M2 and M3 in the logic region L and the analog region A.

The zero wiring layer M0, the first wiring layer M1, the second wiring layer M2, and the third wiring layer M3 may be in the insulating layer 140, 150, 155, 160, and 165 in above order, vertically.

The insulating layer 105 may include first to fifth insulating layers 140, 150, 155, 160, and 165. The first to fifth insulating layers 140, 150, 155, 160, and 165 within the insulating layer 105 may be known individually as an interlayer insulating layer. Each of the first to fifth insulating layers 140, 150, 155, 160, and 165 may comprise an oxide film (e.g., silicon dioxide, which may be undoped or doped with fluorine or boron and/or phosphorous), and may comprise more than one such layer (e.g., a doped oxide layer with an undoped oxide cap layer thereon).

The first insulating layer 140 may be formed on the substrate 110 having the photodiode region PD1 and PD2, the pixel gate 132, and the logic gate 122 formed thereon. That is, the first insulating layer 140 may be a PMD (Pre Metal Dielectric) in a sense that the first insulating layer 140 covers the photodiode regions PD1 and PD2, the pixel gate 132, and the logic gate 122, and is formed before formation of wiring layers M0˜M3.

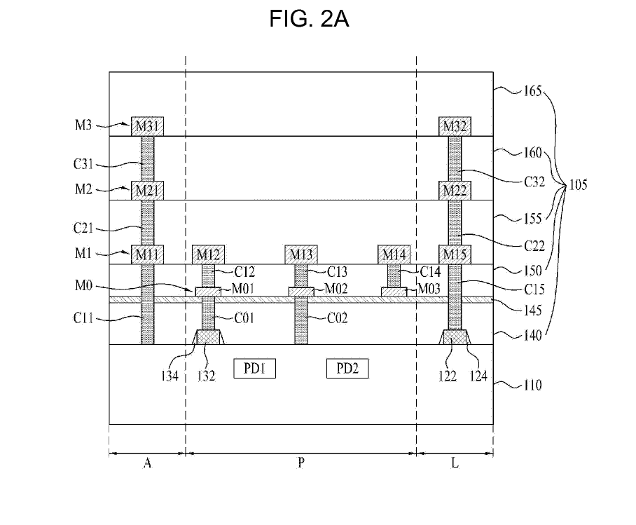

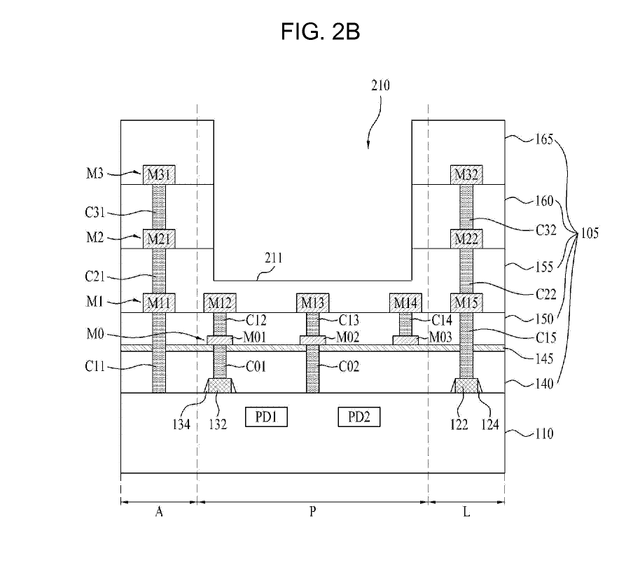

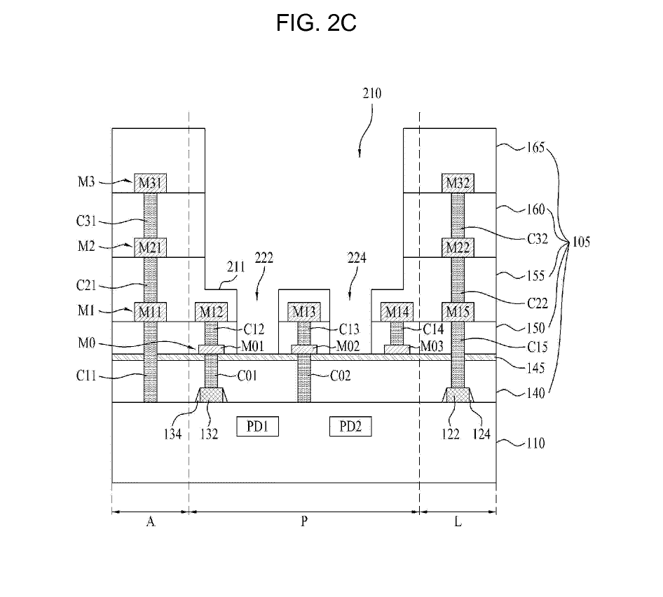

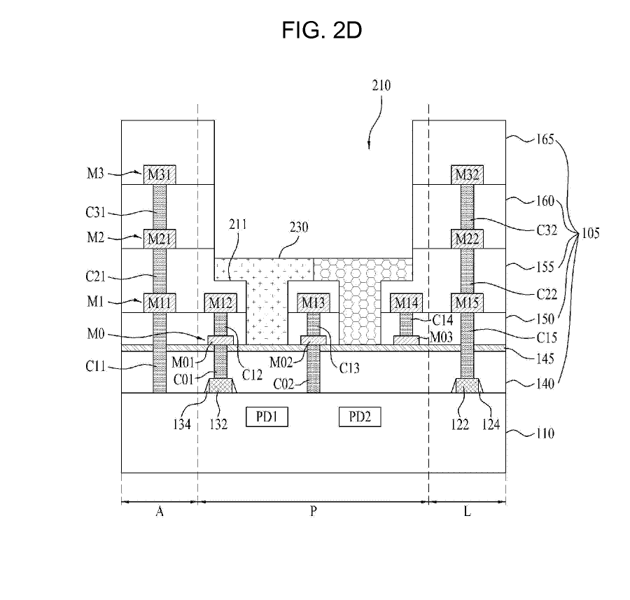

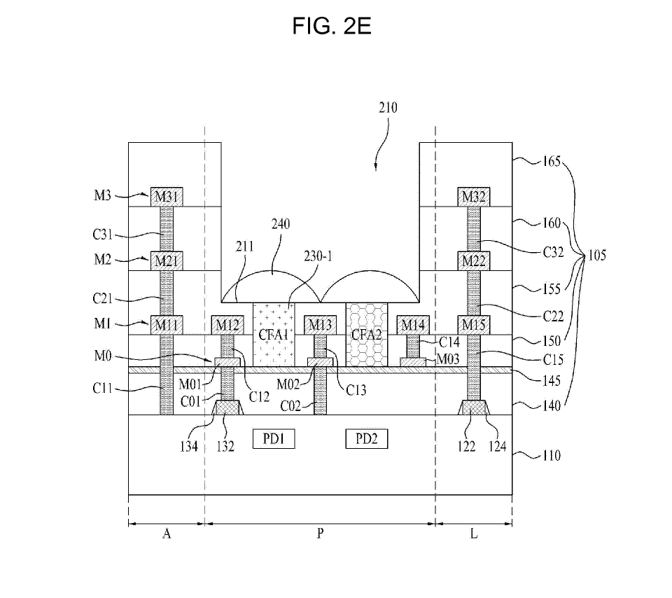

The etch stop film 145 is formed on the first insulating layer 140 at the pixel region P, the logic region L, and the analog region A. For an example, the etch stop film 145 may comprise a silicon nitride film (for example, SiN), with a thickness less than 0.1 μm. The etch stop film 145 may serve as an etch stop film when the insulating layers 150 and 155 are etched for forming second trenches 222, and 224 (See FIG. 2C) to be described later. The etch stop film 145 can prevent the substrate 110 from being damaged by the etching.

The zero wiring layer M0 is formed on the etch stop film 145 in the pixel region P. The zero wiring layer M0 may comprise plural metal wires M01, M02, and M03 spaced apart from one another. The zero wiring layer M0 may be positioned not to vertically overlap with the photodiode regions PD1 and PD2.

The zero wiring layer M0 may function as a GIC (Global interconnection) of the transistors in the pixel region S1. That is, the zero wiring layer (for example, M01) can connect gates (for example, 132) of one of the transistors (for example, the transfer transistors) of the plurality of the unit pixels to one another.

The zero wiring layer M0 may include a first zero layer wire (for example, M01) for connecting gates of the transfer transistors of the plurality of the unit pixels to one another, a second zero layer wire (not shown) for connecting gates of the select transistors of the plurality of the unit pixels to one another, and a third zero wiring layer (not shown) for connecting gates of the reset transistors of the plurality of the unit pixels to one another.

The zero wiring layer M0 may have a structure comprising a stack of a conductive layer (e.g., aluminum; not shown) and a barrier metal layer (e.g., TiN or a Ti/TiN bilayer; not shown). The conductive layer may alternatively include at least one of tungsten and copper, or an alloy including at least one of the tungsten and copper. Also, the barrier layer prevents ions of the conductive layer from diffusing into the substrate 110, and may comprise a metal including at least one of Ni, Ti, Ta, Pt, and Mo.

The zero contact C01 may connect the zero wiring layer M01 to the logic gate 132 and pass through the etch stop film 145 and the first insulating layer 140, and the zero contact C02 may connect the zero wiring layer M02 to the substrate 110 and pass through the etch stop film 145 and the first insulating layer 140.

For example, the pixel gate 132 may be a gate of one of the transistors (for example, the transfer transistors TX) and have the same function as a transistor gate in the pixel region P. And, the zero contact C01 may be plural each in contact with one of the gates of the transfer transistors at the pixel region P.

Also, the zero wiring layer (for example, including M01) may be in contact with all of the plurality of zero contacts C01 respectively connected to the gates of the transfer transistor and other transistors in the pixel region P. The zero wiring layer (for example, including M01) is electrically connected to the plurality of the zero contacts C01 to embody the global interconnection.

The second insulating layer 150 may be formed on the zero wiring layer M0 and the etch stop film 145. For example, the second insulating layer 150 may be formed on the etch stop film 145 in the pixel region P, the logic region L, and the analog region A.

The first wiring layer M1 is formed on the second insulating layer 150 in the pixel region P, the logic region L, and the analog region A. There may be no wiring layer between the first wiring layer M12, M13, and M14 and a light receiving portion in the pixel region P, and between the zero wiring layer M0 and the first wiring layer M1. In this case, the light receiving portion may include at least one of the microlens 240, the color filter layer 230-1, and one or more photodiodes (e.g., PD1 and/or PD2).

The first wiring layer M1 may be plural, and the plurality of first layer wires M11˜M15 may be in the pixel region P, the logic region L, and the analog region A, spaced apart from one another.

The first contact C11 may connect the first layer wire M11 in the analog region A to the substrate 110 and pass through the second insulating layer 150, the etch stop film 145, and the first insulating layer 140.

The first contacts C12 to C14 may connect the zero layer wires M0 to the first layer wires M12, M13, and M14 in the pixel region P and pass through the second insulating layer 150. The first contact C15 may connect the first layer wire M15 to the logic gate 122 in the logic region L and pass through the second insulating layer 150, the etch stop film 145 and the first insulating layer 140.

The third insulating layer 155 may be formed on the first wiring layer M1 and the second insulating layer 150.

The second wiring layer M2 may be formed on the third insulating layer 155 in the analog region A and the logic region L. The second wiring layer M2 may include plural wires, and the plurality of second layer wires M21 and M22 may be in the logic region L and the analog region A, spaced apart from one another.

The second contact C21 may connect the first layer wire M11 to the second layer wire M21 and pass through the third insulating layer 155 at the analog region A, and the second contact C22 may connect the first wiring layer M15 to the second wiring layer M22 and pass through the third insulating layer 155 at the logic region L.

The fourth insulating layer 160 may be formed on the second wiring layer M2 and the third insulating layer 155.

The third wiring layer M3 may be formed on the fourth insulating layer 160 in the analog region A and the logic region L. The third wiring layer M3 may include plural wires, and the plurality of third layer wires M31 and M32 may be in the logic region L and the analog region A, spaced apart from one another.

The third contact C31 may connect the second layer wire M21 to the third layer wire M31 and pass through the fourth insulating layer 160 in the analog region A, and the third contact C32 may connect the second layer wire M22 to the third layer wire M32 and pass through the fourth insulating layer 160 in the logic region L.

The fifth insulating layer 165 may be formed on the third wiring layer M3 and the fourth insulating layer 160.

Each of the first to fifth insulating layers 140, 150, 155, 160, and 165 may be or comprise a single layer or double layer of oxide and/or nitride as described herein.

Each of the zero contacts C01 and C02 and the first to third contacts C11 to C15, C21 to C22, and C31 to C32 may include a conductive layer and a barrier layer. In another embodiment, there may be at least one insulating layer (not shown) on the fifth insulating layer 165 in the pixel region P, the logic region L, and the analog region A additionally, and at least one wiring layer (not shown) in the at least one additional insulating layer in the logic region and the analog region, additionally.

The first trench 210 and the second trenches 222 and 224 may be in the insulating layers 105. For example, the first trench 210 may have a size corresponding to the pixel region P2. The first trench 210 does not expose the first wiring layer M12, M13, and M14, and there may be a portion of the third insulating layer 155 between a bottom 211 of the first trench 210 and the first wiring layer M12, M13, and M14. The bottom 211 of the first trench 210 may be between the first wiring layer M1 and the second wiring layer M2. However, in another embodiment, the first trench 210 may expose the first wiring layer M12, M13, and M14.

There may be second trenches 222 and 224 in the third insulating layer 155 and the second insulating layer 150 under the first trench 210 that are matched or aligned to the photodiode regions PD1 and PD2. The second trenches 222 and 224 may expose the etch stop film 145. The second trenches 222 and 224 may be formed to extend from a space between the zero layer wires M01, M02, and M02 to a space between the first layer wires M12, M13, and M14 adjacent to one another in the pixel region P. Openings of the second trenches 222 and 224 may be exposed by or in the first trench 210.

The color filter layer 230-1 may be formed in the second trenches 222 and 224. The color filter layer 230-1 may include a plurality of color filters CFA1 and CFA2, for an example, a blue color filter, a green color filter, and/or a red color filter, although typically a single trench 222 or 224 includes only a single color filter (e.g., red, blue or green). Each of the color filters CFA1 and CFA2 may be matched to or aligned with the photodiode regions PD1 and PD2. In this case, the blue color filter, the green color filter, and the red color filter may have thicknesses different from one another.

The color filter layer 230-1 may have an uppermost surface on the same plane with the bottom or lowermost surface 211 of the first trench 210. Alternatively, the uppermost surface of the color filter layer 230-1 may be at the same height as the bottom or lowermost surface 211 of the first trench 210.

The color filter layer 230-1 may have an underside or lowermost surface even with or under the zero wiring layer M0 and may be in contact with the etch stop film 145. The color filters CFA1 and CFA2 aligned to the photodiode regions PD1 and PD2 may be spaced from each other, and the lowermost surface 211 of the first trench 210 may be between the color filters CFA1 and CFA2.

The uppermost surface of the color filter layer 230-1 may be between the first wiring layer M1 and the second wiring layer M2. However, in another embodiment, the uppermost surface of the color filter layer 230-1 may be higher than the uppermost surface of the first wiring layer M1.

The color filter layer 230-1 may be between adjacent zero layer wires M01 and M02, and M02 and M03, and adjacent to first layer wires M11 and M12, M12 and M13, M13 and M14, and M14 and M15.

The microlens 240 may be formed on the color filter layer 230-1 and the bottom of the first trench 210. The microlens 240 may be aligned with the photodiode regions PD1 and PD2 or the color filters CFA1 and CFA2 in a vertical direction, and may have, but not be limited to, a convex surface (for example, a hemispherical) shape for focusing the light.

In order to protect the color filter layer 230-1 from water and scratches, a planarizing layer (not shown) may be formed between the color filter layer 230-1 and the microlens 240.

The microlens 240 may be formed on the planarizing layer in the pixel region P, and the microlens 240 may match to or align with the photodiode regions PD1 and PD2 or the color filters 240, and may have, but not be limited to, a convex surface (for example, a hemispherical) shape for focusing the light.

The microlens 240 may be formed on the color filters CFA1 and CFA2 and the lowermost surface 211 of the first trench 210. Adjacent microlenses 240 may be in contact with each other on the lowermost surface of the first trench 210.

The color filter layer 230-1 is positioned between adjacent zero layer wires M01 and M02, and M02 and M03, and adjacent first layer wires M11 and M12, M12 and M13, M13 and M14, and M14 and M15, to reduce a light path between the photodiode regions PD1 and PD2 and the microlens 240, and thereby reduce or prevent light loss and improve sensitivity.

FIGS. 2A to 2E illustrate sections showing the steps of a method for manufacturing an image sensor in accordance with an embodiment of the invention.

Referring to FIG. 2A, photodiode regions PD1 and PD2 are formed in a substrate 110 in a pixel region P. Though FIG. 2A illustrates only two photodiodes, the embodiment is not limited to this, but a plurality of photodiodes may be formed in the substrate 110. That is, the pixel region P may be divided into a plurality of unit pixels, and the photodiode regions PD1 and PD2 may be formed in the substrate 110 matched or corresponding to each of the unit pixels.

For example, n type impurities may be injected into a p type semiconductor substrate 110 to form a PN junction therein to form the photodiode regions PD1 and PD2. Then, a device isolation film (not shown) may be formed in the semiconductor substrate 110 for partitioning a device isolation region and an active region. The device isolation film may be formed by STI (Shallow Trench Isolation) or LOCOS (Local Oxidation of Silicon). In another embodiment, reversal of an order of formation of the photodiode regions PD1 and PD2 and the device isolation film (not shown) may be performed or suggested.

When the photodiode regions PD1 and PD2 are formed in the pixel region P, source and drain regions (not shown) adjacent to a logic gate 122 to be described later may be formed in the substrate 110 in the logic region L. Alternatively, the source and drain regions of the transistors in one or more regions (e.g., the logic region L, the logic and pixel regions L and P, or the logic, pixel and analog regions L, P and A) may be formed after formation of transistor gates in those regions.

Gates (for example, 122 and 132) of transistors may be formed on the substrate 110 in the pixel region P, the logic region L, and the analog region A by sputtering or chemical vapor deposition. Prior to forming the gates, one or more gate oxide layers may be formed by thermal oxidation. Different regions of the substrate (e.g., L, P or A) may have gate oxide layers with different thicknesses. Spacers 124 and 134 may be formed at sidewalls of the gates 122 and 132, respectively. In this case, the gates 122 and 132 may have a stack structure comprising a gate insulating film and a polysilicon layer thereon.

In this case, the gate 132 formed in the pixel region P may be a gate of at least one of the transistors in the unit pixel, and the gate 122 in the logic region L may be a gate of the logic transistor.

Then, a first insulating layer 140 is formed on the substrate 110 in the pixel region P, the logic region L, and the analog region A to cover the gates 122 and 132. Thereafter, an etch stop film 145 is formed on the first insulating layer 140 in the pixel region P, the logic region L, and the analog region A. For example, a silicon nitride film (for example, SiN) may be deposited on the first insulating layer 140 at a thickness below 0.1μm to form the etch stop film 145.

Zero contacts C01 and C02 are formed to be connected to the logic gate 132 and the substrate 110, and pass through the etch stop film 145 and the first insulating film 140, respectively.

Then, the zero wiring layer M0 is formed (e.g., by blanket deposition and photolithography) in contact with the zero contacts C01 and C02. The zero wiring layer M0 may comprise a conductive metal or material such as Ti, TiN, W, Al, or a combination thereof. A second insulating layer 150 is then formed on the zero wiring layer M0 and the etch stop film 145 in the pixel region P, and on the etch stop film 145 in the logic region L and the analog region A, to contain the zero wiring layer M0 in the pixel region P.

Then, a first contact C11 connected to the substrate 110 in the analog region A and passing through the first and second insulating layers 145 and 150, additional first contacts C12, C13, and C14 connected to the zero wiring layer M0 in the pixel region P and passing through the second insulating layer 150, and a further first contact C15 connected to the logic gate 122 in the logic region L and pass through the first and second insulating layers 145 and 150 are formed.

Then, a first wiring layer M1 connected to the first contacts C11 to C15 is formed (e.g., by blanket deposition of one or more conductive metals and/or materials and photolithography), and a third insulating layer 155 is formed on the second insulating layer 150 and the first wiring layer M1 in the analog region A, the pixel region P, and the logic region L to contain the first wiring layer M1 connected to the first contacts C11 to C15. For example, the first layer wire M11 in the analog region connected to the first contact C11, the first layer wires M12, M13, and M14 in the pixel region P respectively connected to the first contacts C12, C13, and C14, and the first layer wire M15 in the logic region L connected to the first contact C15 may be formed on the second insulating layer 150.

Then, a second contact C21 connected to the first layer wire M11 and passing through the third insulating layer 155 is formed in the analog region A, and a second contact C22 connected to the first layer wire M15 and passing through the third insulating layer 155 is formed in the logic region L.

Then, a second wiring layer M2 connected to the second contacts C21, and C22 is formed in the same or similar manner as the first wiring layer M1, and a fourth insulating layer 160 is formed on the third insulating layer 155 and second wiring layer M2 in the analog region A and the logic region L to contain the second wiring layer M2 connected to the second contacts C21, and C22. The fourth insulating layer 160 is formed on only the third insulating layer 155 in the pixel region P.

Then, a third contact C31 connected to the second layer wire M21 and passing through the fourth insulating layer 160 is formed in the analog region A, and a second contact C32 connected to the second layer wire M22 and passing through the fourth insulating layer 160 is formed in the logic region L.

Then, a third wiring layer M3 connected to the third contacts C31 and C32 is formed in the same or similar manner as the second wiring layer M2, and a fifth insulating layer 165 is formed on the fourth insulating layer 160 and third wiring layer M3 in the analog region A and the logic region L to contain the third wiring layer M3 connected to the third contacts C31 and C32. The fifth insulating layer 165 is formed on only the fourth insulating layer 160 in the pixel region P.

In another embodiment, a plurality of additional insulating layers may be provided on the fifth insulating layer 165, each containing an additional wiring layer in the analog region A and the logic region L, but not in the pixel region P.

Each of the first to fifth insulating layers 140, 150, 155, 160, and 165 may comprise an insulating oxide and/or nitride, as described herein. For example, the first to fifth insulating layers 140, 150, 155, 160, and 165 may comprise a single or double layer of BPSG (Borophosphosilicate Glass), PSG (Phosphosilicate Glass), and USG (Undoped Silicate Glass).

Each of the zero contacts C01 and C02 and the first to third contacts C11 to C15, C21 to C22, and C31 to C32 may have a structure comprising a stack of a barrier layer and a conductive layer. The conductive layer may include at least one of tungsten and copper, or an alloy including at least one of tungsten and copper. The barrier layer may comprise Ni, Ti, and/or Ta for preventing ions of the conductive layer from diffusing into the substrate 110 or the pixel gate 132. The wiring layers (for example, M01 and M02) and the contacts (for example, C01 and C02) may be formed by a damascene or dual damascene process.

Referring to FIG. 2B, a portion of each of the fifth insulating layer 165, the fourth insulating layer 160, and the third insulating layer 155 in the pixel region P are etched by selective photolithography and etching to form a first trench 210 matched to or aligned with the pixel region P. In one embodiment, the first trench 210 does not expose the first layer wires M12, M13, and M14, and a portion of the third insulating layer 155 may exist between a bottom 211 of the first trench 210 and the first layer wires M12, M13, and M14. However, in another embodiment, the first trench 210 may expose the first layer wires M12, M13, and M14. For example, the bottom 211 of the first trench 210 may be between the first layer wires M12, M13, and M14 and the second wiring layer M2. The depth of the trench can be controlled by controlling the time of the etch process.

A reason why the first trench 210 is formed by removing the insulating layers 165, 160, and 155 in the pixel region P is for reducing the length of a light path between the photodiode regions PD1 and PD2 and the microlens 240 (to be described later) to prevent light loss, thereby improving the sensitivity of the image sensor.

Referring to FIG. 2C, the third insulating layer 155 and the second insulating layer 150 under the first trench 210 is etched selectively to form second trenches 222 and 224 matched to or aligned with the photodiode regions PD1 and PD2. The second trenches 222 and 224 may expose the etch stop film 145. The second trenches 222 and 224 may extend into a space between the zero wiring layers M01, M02, and M03 and between the first layer wires M12, M13, and M14 in the pixel region P.

Referring to FIG. 2D, a color filter material layer 230 is deposited into the first trench 210 to fill the second trenches 222 and 224. The color filter material layer 230 may include a plurality of color filters (for example, CFA1 and CFA2), for an example, a blue color filter, a green color filter, and a red color filter each matched to or aligned with a corresponding photodiode region (e.g., PD1 or PD2). In one embodiment, the color filter material for each different color is deposited separately. For example, the color filter material for a first color (e.g., green) may be blanket deposited (e.g., by spin-coating), and the excess color filter material removed by an etch back process. The color filter material for the first color can be removed from the first and second trenches above the photodiodes corresponding to other colors by selectively masking the color filter material over the photodiodes corresponding to the first color, then etching the exposed color filter material. The color filter material for a second color (e.g., blue) may be formed in the same or similar manner (e.g., spin-coating and etching back). If there is an additional color, the color filter material over the photodiodes corresponding to the first and second colors can be selectively masked, then the exposed color filter material etched so that color filter material for an additional color (e.g., red) can be deposited. The color filter material for a final color (e.g., red) may be formed in a similar manner (e.g., spin-coating and etching back), but selective masking and etching is not necessarily performed. In this case, the blue color filter, the green color filter, and the red color filter may have thicknesses different from one another.

The color filter material layer 230 may also exist on the lowermost surface 221 of the first trench, outside the second trenches 222 and 224, and over the second trenches 222 and 224. That is, the color filter material layer 230 may have an uppermost surface higher than the bottom surface 211 of the first trench 210.

Referring to FIG. 2E, the color filter material layer 230 is etched back to remove the color filter material layer 230 from outside the second trenches 222 and 224 to form color filter layer 230-1 in the second trenches 222 and 224. For an example, by removing the color filter material layer 230 from outside the second trenches 222 and 224, the bottom surface 211 of the first trench 210 may be exposed.

An underside of lowermost surface of the color filter layer 230-1 may be under or even with the zero wiring layer M0 in contact with the etch stop layer 145. The color filters CFA1 and CFA2 aligned to the photodiode regions PD1 and PD2 may be spaced apart from each other. In one embodiment (not shown), the bottom of the first trench 210 may be between the color filters CFA1 and CFA2.

Then, microlenses 240 are formed on the color filter layer 230-1 and the bottom surface 211 of the first trench 210. The microlenses 240 may be aligned to the photodiode regions PD1 and PD2 and/or the color filters CFA1 and CFA2 in a vertical direction, and may have, but not be limited to, a convex surface (for example, a hemisphere) for focusing light passing through the microlenses 240.

In another embodiment, a planarizing layer (not shown) may be formed after the color filter layer 230 is formed and before the microlenses 240 are formed, to protect the color filter layer 230 or 230-1 from water and scratches, additionally.

The manufacturing method described herein can reduce the distance between the photodiode regions PD1 and PD2 and the corresponding microlenses, leading to reduced optical loss and improved sensitivity by forming the color filter layer 230 in the second trenches 222 and 224 (in turn, formed by removing a portion of the insulating layer 150 between the etch stop film 145 and the first wiring layer M1).

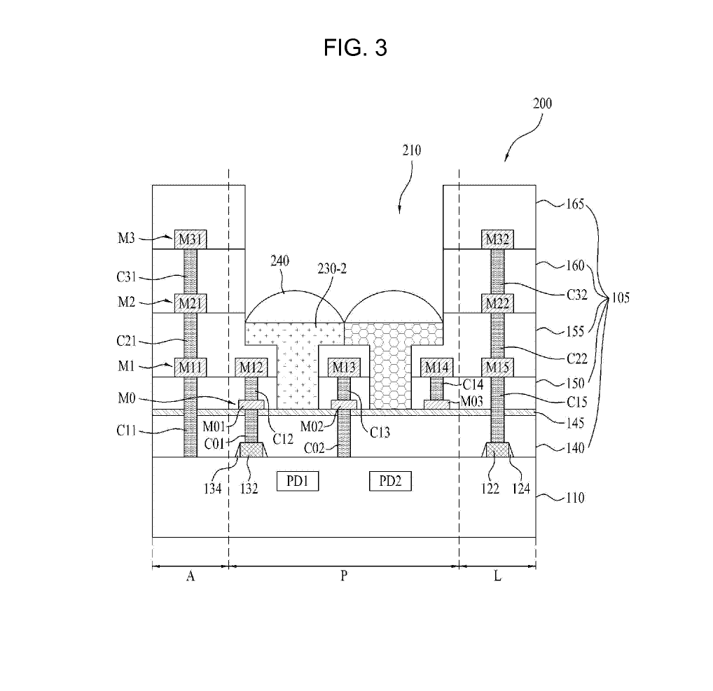

FIG. 3 illustrates a section of an image sensor 200 in accordance with another embodiment of the invention. Elements having reference numbers the same with the reference numbers in FIGS. 1 and 2A-2E denote elements identical to the elements in FIGS. 1 and 2A-E, and description(s) repetitive with the description(s) made already will be omitted or briefed.

Referring to FIG. 3, the image sensor 200 may be a variation of the image sensor 100 described in the embodiment shown in FIG. 1. The image sensor 200 may also have a color filter layer 230-2 outside of the second trenches 222 and 224. That is, an uppermost surface of the color filter layer 230-2 may be higher than the bottom or lowermost surface of the first trench 210. Moreover, in another embodiment, the uppermost surface of the color filter layer 230-2 may be higher than the uppermost surface of the first wiring layer M1.

A thickness of the color filter layer 230-2 or a position of the uppermost surface of the color filter layer 230-2 may be changed or adjusted according to a thickness of the color filter material layer 230 removed by the etch back process described with reference to FIG. 2E.

Characteristics, structures, effects, and so on described in above embodiments are included in at least one of embodiments, but are not limited to only one embodiment invariably. Furthermore, it is apparent that the features, the structures, the effects, and so on described in the embodiments can be combined, or modified with other embodiments by persons skilled in this field of art. Therefore, it is required to understand that such combination and modification is included to scope of the present invention.

What is claimed is:

1. An image sensor having a pixel region, a logic region, and an analog region, comprising:
one or more photodiode regions in a substrate in the pixel region;
an insulating layer on the substrate containing a zero wiring layer in the pixel region, a first wiring layer in the pixel region, the logic region, and the analog region, and a second wiring layer in the logic region and the analog region;
a first trench in a portion of the insulating layer in the pixel region;
second trenches in a bottom of the first trench, matched to or aligned with the photodiode region(s);
color filter layers in respective ones of the second trenches; and
microlenses on respective ones of the color filter layers.

2. The image sensor as claimed in claim 1, wherein the color filter layer has an uppermost surface between the first wiring layer and the second wiring layer.

3. The image sensor as claimed in claim 1, wherein the color filter layer is between adjacent wires in the zero wiring layer and adjacent wires in the first wiring layer.

4. The image sensor as claimed in claim 1, wherein the color filter layer has an uppermost surface coplanar with a bottom or lowermost surface of the first trench.

5. The image sensor as claimed in claim 1, wherein the color filter layer has an uppermost surface higher than a bottom or lowermost surface of the first trench.

6. The image sensor as claimed in claim 1, wherein the color filter layer includes:
a plurality of color filters, each color filter in a respective one of the second trenches,
wherein a bottom or lowermost surface of the first trench is between adjacent color filters.

7. The image sensor as claimed in claim 6, wherein the microlenses are on the color filters and a lowermost surface of the first trench.

8. The image sensor as claimed in claim 1, comprising a plurality of photodiode regions in the substrate in the pixel region, wherein each photodiode corresponds to a unique one of the second trenches, a unique one of the color filters, and a unique one of the microlenses.

9. The image sensor as claimed in claim 8, further comprising a first plurality of contacts in the pixel region between the zero wiring layer and the photodiode regions, a second plurality of contacts in the pixel region between the first wiring layer and the zero wiring layer, a third plurality of contacts in the logic region and the analog region between the first wiring layer and the substrate, and a fourth plurality of contacts in the logic region and the analog region between the second wiring layer and the first wiring layer.

10. A method for manufacturing an image sensor having a pixel region, a logic region, and an analog region, comprising:
forming a photodiode region in a substrate in the pixel region;
forming an insulating layer on the substrate containing a zero wiring layer in the pixel region, a first wiring layer in the pixel region, the logic region, and the analog region, and a second wiring layer in the logic region and the analog region;
forming a first trench by etching a portion of the insulating layer in the pixel region;
forming second trenches by etching portions of the insulating layer under the first trench;
forming color filter layers in respective ones of the second trenches; and
forming microlenses on respective ones of the color filter layers.

11. The method as claimed in claim 10, wherein the first trench has a bottom or lowermost surface between the first wiring layer and the second wiring layer.

12. The method as claimed in claim 10, wherein each of the second trenches extends between adjacent wires in the zero wiring layer and between adjacent wires in the first wiring layer.

13. The method as claimed in claim 10, further comprising forming an etch stop film over the substrate and on a first insulating sublayer of the insulating layer, and each of the second trenches exposes the etch stop film.

14. The method as claimed in claim 13, wherein the zero wiring layer is formed on the etch stop film.

15. The method as claimed in claim 10, wherein the color filter layer has an uppermost surface coplanar with or higher than the bottom or lowermost surface of the first trench.

16. The method as claimed in claim 10, comprising a plurality of photodiode regions in the substrate in the pixel region, wherein each photodiode corresponds to a unique one of the second trenches, a unique one of the color filters, and a unique one of the microlenses.

17. The method as claimed in claim 16, wherein each of the second trenches is matched to or aligned with a respective photodiode region.

18. The method as claimed in claim 10, wherein forming the insulating layer comprises:
forming a first insulating sublayer of the insulating layer on the substrate,
forming the zero wiring layer on or in the first insulating sublayer,
forming a second insulating sublayer of the insulating layer on the first insulating sublayer and the zero wiring layer,
forming the first wiring layer on or in the second insulating sublayer,
forming a third insulating sublayer of the insulating layer on the second insulating sublayer and the first wiring layer, and
forming a second wiring layer on or in the third insulating sublayer.

19. The method as claimed in claim 10, further comprising:
forming a first plurality of contacts in the pixel region between the zero wiring layer and the photodiode regions,
forming a second plurality of contacts in the pixel region between the first wiring layer and the zero wiring layer, and a third plurality of contacts in the logic region and the analog region between the first wiring layer and the substrate, and
forming a fourth plurality of contacts in the logic region and the analog region between the second wiring layer and the first wiring layer.
